(19) United States
(12) Patent Application Publication
(10) Pub. No.: US 2006/0094226 A1
(43) Pub. Date: May 4, 2006

(54) Bumping process

(75) Inventors: Min-Lung Huang, Kaohsiung (TW); Yi-Hsin Chen, Kaohsiung (TW); Jia-Bin Chen, Tainan (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/229,556

(22) Filed: Sep. 20, 2005

(30) Foreign Application Priority Data
Oct. 28, 2004 (TW) 93132703

(51) Int. Cl. H01L 21/44

(52) U.S. Cl. 438/613; 438/652; 438/687

(57) ABSTRACT

A bumping process is provided as following: at first, providing a wafer, then forming a first photo-resist layer on a active surface of the wafer and forming at least a first opening on the first photo-resist layer; and forming a copper pillar in the first opening; then forming a second photo-resist layer on the first photo-resist layer and forming at least a second opening on the second photo-resist layer; finally forming a solder layer in the second opening to attach the solder layer on the copper pillar, and removing the first and second photo-resist layer.

This application claims the benefit of Taiwan application Serial No. 93132703, filed Oct. 28, 2004, the subject matter of which is incorporated herein by reference.

### BACKGROUND OF THE INVENTION

1. Field of the Invention

The invention relates in general to a semiconductor manufacturing process, and more particularly to a bumping process of wafer.

2. Description of the Related Art

In the semiconductor industry, the manufacturing process of integrated circuits (IC) is divided into three main stages: the manufacturing of wafer, the manufacturing of IC, and the package of IC. The die is manufactured according to the steps of manufacturing the wafer, performing circuit design, performing several mask manufacturing processes, and dividing the wafer. Every die formed by dividing the wafer is electrically connected to a carrier via a bonding pad disposed on the die to form a chip package structure. The chip package structure is further categorized into three types, namely, the wire bonding type, the flip chip bonding type, and the tape automatic bonding type.

Referring to FIG. 1˜FIG. 4, flowcharts of a bumping process of a conventional wafer are shown. At first, referring to FIG. 1, an under bump metallurgy 110 is formed on the entire surface of a wafer 100 and is covered up by a photo-resist layer 120. Next, referring to FIG. 2, several openings 122 are formed on a photo-resist layer 120 using the imaging technology of exposure and development, and the positions of the openings 122 correspond to several bonding pads 102 positioned on the wafer 100. Afterwards, referring to FIG. 3, the photo-resist layer is used as a mask in copper electroplating treatment, so that the educts of copper in the electroplating solution can be adhered onto a portion of the surface using the under bump metallurgy 110 as an electroplating-seed layer to form a bump structure similar to a copper pillar 112. Next, referring to FIG. 4, the same photo-resist layer 120 is used as the mask in the solder electroplating treatment to form a mushroom-like solder layer 114 on the surface of the copper pillar 112, while the solder layer 114 which can be made of materials such as tin-lead alloy with a low melting point for instance, can therefore be reflown to be a spherical bump so that every chip (not illustrated in the diagram) of the wafer 100 is able to electrically connected to an external circuit board (not illustrated in the diagram).

It is noteworthy that since the copper pillar 112 and the solder layer 114 disposed thereon are formed in the same opening 122 of the photo-resist layer 120, the depth of the opening 122 of the photo-resist layer 120 is higher than the height of the copper pillar 112, causing difficulties in exposure and development. Furthermore, the solder layer 114, after filling the opening 122 of the photo-resist layer 120, will be projected from the photo-resist layer 120, so that the two adjacent solder layers 114 are easily electrically connected to each other, causing short-circuit and affecting the reliability of subsequent packages.

### SUMMARY OF THE INVENTION

It is therefore the object of the invention to provide a bumping process applicable to a wafer to enhance the quality of the copper pillar and the solder layer in the bumping process.

The invention provides a bumping process. The bumping process comprises the steps of: firstly, providing a chip; then, forming a first photo-resist layer on an active surface of the chip and forming at least a first opening on the first photo-resist layer; afterwards, forming a copper pillar in the first opening; next, forming a second photo-resist layer on the first photo-resist layer and forming at least a second opening on the second photo-resist layer; finally, forming a solder layer in the second opening to attach the solder layer on the copper pillar, and then removing the first and the second photo-resist layers.

According to the preferred embodiment of the invention, the above first photo-resist layer can be formed by, for example, coating a photosensitive photoresist and forming a first opening using exposure and development. Besides, the second photo-resist layer can be formed by, for example, coating a photosensitive photoresist and forming a second opening using exposure and development.

According to the preferred embodiment of the invention, prior to the above step of forming the first photo-resist layer, further comprises forming a re-distribution layer (RDL) and/or an under bump metallurgy on an active surface of the chip with a portion of the surface of the under bump metallurgy being exposed in the first opening. The method of forming an RDL comprises sputtering, evaporating or electroplating. Besides, in the step of forming the copper pillar, the under bump metallurgy can be used as an electroplating-seed layer to be dipped into an electroplating solution for the educts of copper to be adhered onto the under bump metallurgy in the first opening.

The invention adopts the first and the second photo-resist layers whose openings have different sizes to respectively form the copper pillar and the solder layer in the first opening and the second opening. Therefore, a solder layer with larger cross-section can be formed on the copper pillar to reduce the height of the second photo-resist layer and effectively avoid short-circuiting between two adjacent bump structures, so as to enhance the reliability of package.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1˜FIG. 4 respectively are a flowchart of a bumping process of a conventional wafer; and

FIG. 5˜FIG. 11 respectively are a flowchart of a bumping process according to a preferred embodiment of the invention.

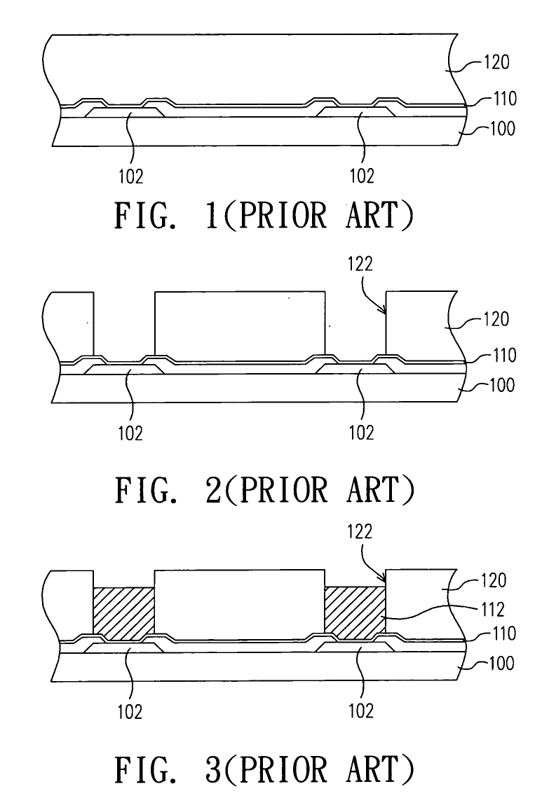

### DETAILED DESCRIPTION OF THE INVENTION

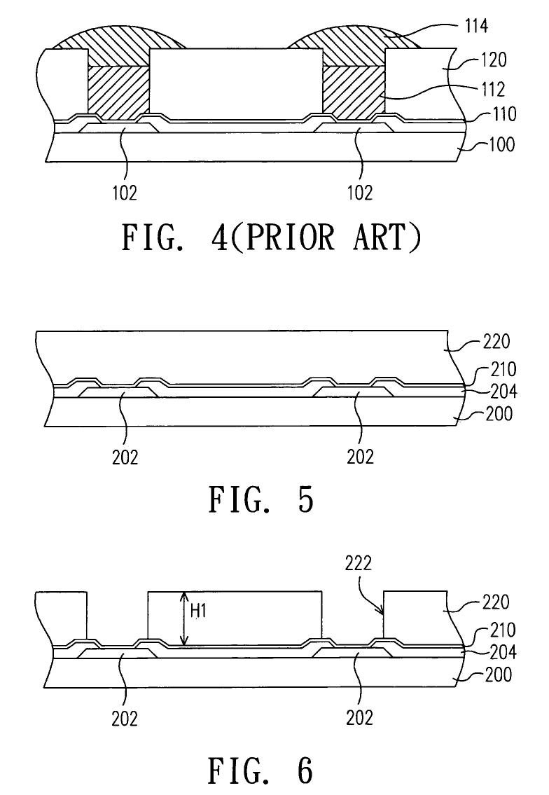

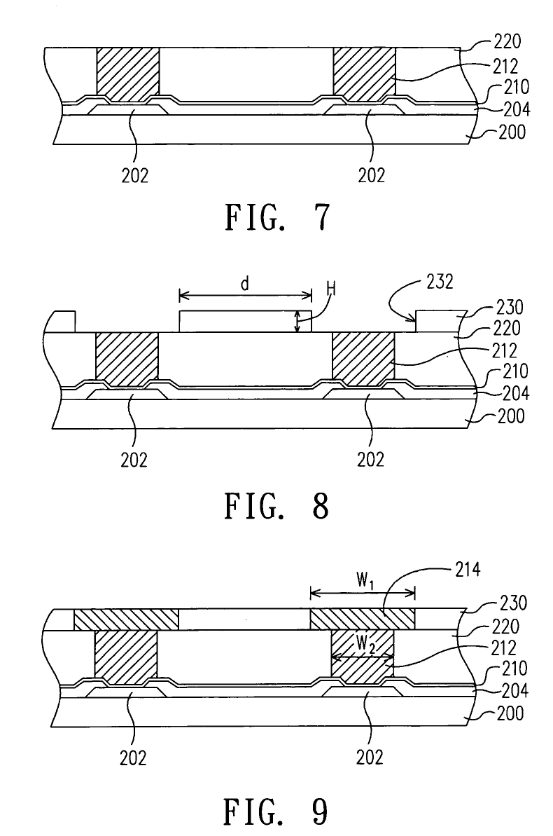

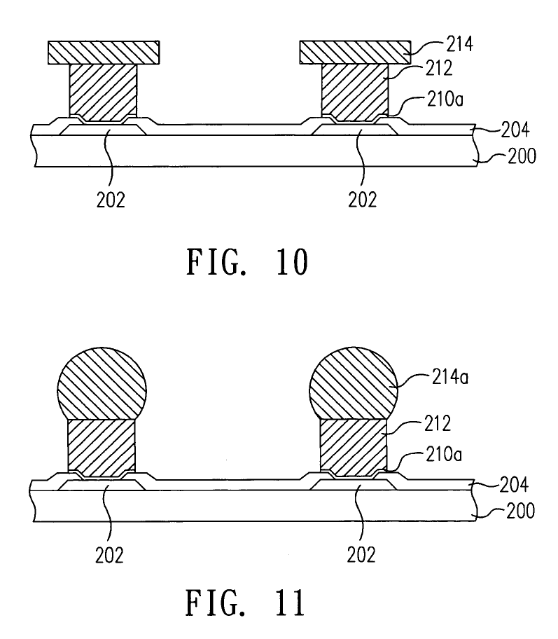

Referring to FIG. 5˜FIG. 11, flowcharts of a bumping process according to a preferred embodiment of the invention are shown. At first, referring to FIG. 5, a wafer 200 is provided, wherein the wafer 200 has several chips (not illustrated in the diagram), and the active surface of every chip has several bonding pads 202 exposed in an opening of a passivation layer. Next, an under bump metallurgy 210 is formed on the entire surface of the wafer 200, wherein the under bump metallurgy 210 can be metals such as copper, nickel or other metals. Next, a photosensitive material is coated on the under bump metallurgy 210 to form a first photo-resist layer 220. The under bump metallurgy 210 can be formed on the surface of the wafer 200 using sputtering, evaporating or electroplating for instance, serving as a seed layer for the copper pillar and the solder layer in subsequent electroplating treatment. The present embodiment is exemplified by the electroplating manufacturing process. If the invention is embodied by non-electroplating manufacturing process, the under bump metallurgy 210 does not need to be formed on the surface of the wafer 200 beforehand. Besides, the active surface of the wafer 200, in response to the chip structure positioned at different contacting positions, can re-manufacture a re-distribution layer (RDL) (not illustrated in the diagram) and form the under bump metallurgy 210 on the RDL to proceed with the subsequent electroplating manufacturing process. Next, a photosensitive material is coated on the under bump metallurgy 210 to form a first photo-resist layer 220.

Next, referring to FIG. 6, several first openings 222 are formed in the first photo-resist layer 220 using the imaging technology of exposure and development, wherein the first openings 222 respectively expose the under bump metallurgy 210 disposed in the bottom thereof. Next, referring to FIG. 7, the under bump metallurgy 210 is used as an electroplating-seed layer in copper electroplating treatment to form a copper pillar 212 of appropriate height in the first opening 222. By controlling parameters such as concentration of copper ions in electroplating solution, current time/ampere and so forth, the height of the copper pillar 212 enables the educts of copper to be adhered onto the under bump metallurgy 210 and filled with the first opening 222. As shown in FIG. 6, FIG. 7, since the depth H1 of the opening of the first photo-resist layer 220 is approximately equal to a determined height of the copper pillar 212, the exposure and development would have better quality producing higher resolution and accuracy.

Next, referring to FIG. 8, a second photo-resist layer 230 is formed by coating a photosensitive material. The technology of the invention differs with conventional technology in that the second photo-resist layer 230 with a larger opening of size W is formed on the first photo-resist layer 220. The second opening 232 of the second photo-resist layer 230 is also formed on the copper pillar 214 and its surrounding first photo-resist layer 220 using the imaging technology of exposure and development. That is, the size W of the second opening 232 is larger than the size of the first opening 222 disposed underneath. Therefore, the height H of the second photo-resist layer 230 is reduced due to the second opening 232 with a larger size W of opening being used so as to enhance the imaging effect. In the present embodiment, every two adjacent openings 232 disposed in the second photo-resist layer 230 are interspaced by a width d, the width d larger than the second photo-resist layer 230 the height of H, and the ratio (d/H) of the width d to the height of the second photo-resist layer 230 is preferably smaller than or equal to 5, lest the second photo-resist layer 230 might be detached from the surface of the first photo-resist layer 220.

Next, referring to FIG. 9, a solder electroplating treatment is applied to the electroplated copper pillar 212, so that a solder layer 214 is formed on the surface of the electroplated copper pillar 212. The solder layer 214 can be made of materials such as tin-lead alloy with a low melting point or other metals. By controlling parameters such as concentration of metal ions in the electroplating solution, the height of the solder layer 214 can also enable the metal educts to be adhered onto the copper pillar 212 and filled with the second opening 232, and form the bump structure of FIG. 9 on every bonding pad 202 of the chip. The cross-section W1 of the solder layer 214 is larger than the cross-section W2 of the copper pillar 212, the occurrence possibility of the short-circuiting between two adjacent solder layers 214 is largely reduced accordingly.

Next, referring to FIG. 10, the first and the second photo-resist layers 220 and 230 are removed, and the portion of the under bump metallurgy 210 not covered by the copper pillar 212 is etched except the portion of the under bump metallurgy 210a disposed at the bottom of the copper pillar 212. Next, the solder layer 214 of FIG. 10 is reflown to form a spherical or semi-spherical solder bump 214a as shown in FIG. 11. Therefore, after the electroplated copper pillar 212 and the bumping process of the solder layer 214 are formed on the surface of the wafer 200, the wafer 200 can be divided into several independent chips (not illustrated in the diagram), every chip can be electrically connected to an external electronic device such as a printed circuit board for instance via the above bump for signals to be transmitted.

It can be seen from the above disclosure that the bumping process of the invention uses multiple manufacturing processes of photoresist-coating, exposure and development to form the first and the second openings with different opening sizes on the first and the second photo-resist layers. The second opening is larger than the first opening, so that the height of the second photo-resist layer is reduced because a larger sizes second opening is used so as to enhance the imaging effect. Besides, two adjacent solder layers are less likely to be short-circuited, thus enhancing the reliability of package.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A bumping process comprising the steps of:
providing a wafer having an active surface;
forming a first photo-resist layer on the active surface of the wafer and forming at least a first opening in the first photo-resist layer;
forming a copper pillar in the first opening;
forming a second photo-resist layer on the first photo-resist layer and forming at least a second opening in the second photo-resist layer;
forming a solder layer in the second opening and enabling the solder layer to be adhered onto the copper pillar; and
removing the first and the second photo-resist layers.

2. The bumping process according to claim 1, wherein the formation of the first photo-resist layer comprises coating a photosensitive material and forming a first opening using exposure and development.

3. The bumping process according to claim 1, wherein the formation of the second photo-resist layer comprises coating a photosensitive material and forming a second opening using exposure and development.

4. The bumping process according to claim 1, wherein after the formation of the wafer, the process further comprises forming a re-distribution layer (RDL) on an active surface of the chip.

5. The bumping process according to claim 4, wherein the formation of the RDL comprises sputtering, evaporating or electroplating.

6. The bumping process according to claim 4, wherein after the formation of the RDL, the process further comprises forming an under bump metallurgy (UBM) on the RDL with a portion of the surface of the under bump metallurgy being exposed in the first opening.

7. The bumping process according to claim 1, wherein after the formation of the wafer, the process further comprises forming an under bump metallurgy (UBM) on an active surface of the wafer with a portion of the surface of the under bump metallurgy being exposed in the first opening.

8. The bumping process according to claim 6, wherein in the step of forming the copper pillar, the under bump metallurgy is used as an electroplating-seed layer and dipped in an electroplating solution for the educts of copper to be adhered onto the under bump metallurgy disposed in the first opening.

9. The bumping process according to claim 7, wherein in the step of forming the copper pillar, the under bump metallurgy is used as an electroplating-seed layer and dipped in an electroplating solution for the educts of copper to be adhered onto the under bump metallurgy disposed in the first opening.

10. The bumping process according to claim 6, wherein in the step of forming the solder layer, the under bump metallurgy is used as an electroplating-seed layer and dipped in an electroplating solution for the educts of tin and lead to be adhered onto the copper pillar and its surrounding first photo-resist layer which are disposed in the second opening.

11. The bumping process according to claim 7, wherein in the step of forming the solder layer, the under bump metallurgy is used as an electroplating-seed layer and dipped in an electroplating solution for the educts of tin and lead to be adhered onto the copper pillar and its surrounding first photo-resist layer which are disposed in the second opening.

12. The bumping process according to claim 6, wherein after the removal of the first and the second photo-resist layers, the process further comprises removing the portion of the under bump metallurgy not covered by the copper pillar.

13. The bumping process according to claim 7, wherein after the removal of the first and the second photo-resist layers, the process further comprises removing the portion of the under bump metallurgy not covered by the copper pillar.

14. The bumping process according to claim 1, wherein after the removal of the first and the second photo-resist layers, the process further comprises reflowing the solder layer.

15. The bumping process according to claim 1, wherein in the step of forming the second opening, the process comprises controlling the second opening to be larger than the first opening, so that the copper pillar and its surrounding first photo-resist layer are all exposed in the second opening.

16. The bumping process according to claim 1, wherein the adjacent second openings disposed in the second photo-resist layer are interspaced by a width larger than the height of the second photo-resist layer, and the ratio of the width to the height of the second photo-resist layer is smaller than or equal to 5.
